(19) United States
(12) Patent Application Publication
(10) Pub. No.: US 2018/0022642 A1
(43) Pub. Date: Jan. 25, 2018

(54) INDEX MATCHING LAYER IN OPTICAL APPLICATIONS

(71) Applicant: Honeywell International Inc., Morris Plains, NJ (US)

(72) Inventors: Ya Qun Liu, Shanghai (CN); Hong Min Huang, Shanghai (CN); Helen X. Xu, Sunnyvale, CA (US)

(21) Appl. No.: 15/595,459

(22) Filed: May 15, 2017

Related U.S. Application Data
(60) Provisional application No. 62/365,121, filed on Jul. 21, 2016.

(51) Int. Cl. C03C 17/34; C23C 16/50; C23C 16/40; B05D 1/00; B05D 3/02

(52) U.S. Cl. CPC C03C 17/3417; B05D 1/005; B05D 3/0254; C23C 16/401; C23C 16/50; C03C 2217/231; C03C 2217/23; C03C 2217/948; C03C 2218/153; C03C 2218/116

(57) ABSTRACT

A layered construct including: a substrate, a transparent electrically conductive layer positioned along an upper surface of the substrate, and an index-matching layer positioned adjacent the transparent electrically conductive layer that reduces the refractive index differential between the transparent electrically conductive layer and the substrate.

### CROSS REFERENCE TO RELATED APPLICATIONS

The present application claims the benefit under Title 35, U.S.C. §119(e) of U.S. Provisional Patent Application Ser. No. 62/365,121, entitled INDEX MATCHING LAYER FOR OPTICAL APPLICATIONS, filed on Jul. 21, 2016, the entire disclosure of which is expressly incorporated by reference herein.

### FIELD OF THE INVENTION

The present disclosure relates generally to index matching layers for optical applications.

### BACKGROUND

Display devices of the touch screen type include grids of transparent, electrically conductive materials such as indium tin oxide (ITO), antimony-doped tin oxide (ATO), aluminum zinc oxide (AZO), etc. formed on glass panels. ITO is most commonly used. The grids of transparent, electrically conductive materials have a different refractive index than the underlying glass or other layers. The differential between the refractive indices may be sufficiently large allowing the user to visually perceive the grid lines when using such devices. This phenomenon is collectively known as “ITO shadow”.

Index matching layers are typically applied over or between ITO layers and the underlying layers to provide a more favorable match between the refractive index of the ITO layer and the refractive indexes of the layers above or below the ITO layer such that the refractive index differential is low enough to reduce the prominence of “ITO shadow” to a user.

To reduce the reflectivity differential between ITO and the substrate, multiple “index matching” layers with alternating high or low refractive indices are deposited, such as by sputtering. The high refractive index materials may be metal oxide or metal nitride, such as Nb₂O₅, TiO₂, SiNₓ, ZrO₂, etc. The low refractive index materials may be SiOₓ, MgF₂, etc. However, these processes are based on expensive vacuum deposition processes, and the coating throughput and substrates size are limited for such deposition processes.

Improvements in the foregoing are desired for matching index layers with high throughput (and ambient environmental processes).

### SUMMARY

The present disclosure provides an index matching layer for optical applications such as touch panel application, either for resistance touch, capacitive touch, infrared touch or haptic touch.

In one exemplary embodiment, a layered construct is provided. The layered construct includes a substrate, a transparent electrically conductive layer positioned along an upper surface of the substrate, and an index-matching layer positioned adjacent the transparent electrically conductive layer, the index-matching layer comprising: a metal oxide layer containing titanium and having a refractive index at least 1.5. The metal oxide layer having the structure below, wherein each R1 is an independent hydrogen, an alkyl group having 1 to 6 carbons, alkylene oxide, or titanium connected groups, wherein each R2 is an independent hydrogen or an alkyl group.

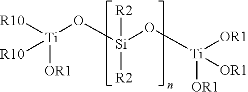

In one more particular embodiment, the index-matching layer further includes a silicon-oxide layer. In one or more particular embodiments of any of the above embodiments, the substrate is glass, quartz, sapphire, polyethylene terephthalate (PET), polyethylene naphthalate (PEN), polyethersulphone (PES), polycarbonate (PC), polyimide (PI) or a combination thereof. In one more particular embodiment of any of the above embodiments, the layered construct has a refractive index differential between the transparent electrically conductive layer and the metal oxide layer between 0 and 1. In one more particular embodiment of any of the above embodiments, the titanium connected groups has the general formula TiₘOₓC_{y}H_{z}, wherein m, x, y, z is independent integer. In one more particular embodiment of any of the above embodiments, the titanium connected groups include Ti(OC₃H₆)₃ and Ti(OC₄H₉)₃. In one more particular embodiment of any of the above embodiments, the metal oxide layer of the layered construct has a refractive index from 1.5 to 2.0. In one more particular embodiment of any of the above embodiments, the metal oxide layer has thickness between 5 to 100 nm. In one more particular embodiment of any of the above embodiments, the index-matching layer is applied as a single metal oxide layer.

In one embodiment, a method of forming a layered construct is provided. The method includes providing a substrate, applying a transparent electrically conductive layer to the substrate, and applying an index-matching coating to the substrate, wherein the index-matching coating is positioned the transparent electrically conductive layer. The index-matching coating includes a metal oxide coating formed with the structure below, wherein each R1 is an independent hydrogen, an alkyl group having 1 to 6 carbons, alkylene oxide, or a titanium connected group, wherein the titanium connected group includes any organic or inorganic groups connected to the titanium atom, and wherein each R2 is an independent hydrogen or an alkyl group.

In one more particular embodiment, the index matching coating further includes a silicon oxide coating. In one more particular embodiment, the metal oxide coating and the silicon oxide coating are applied alternately. In an even more particular embodiment, applying the silicon oxide coating to the substrate is done by CVD, PECVD, spin coating, spray coating, and slit coating. In an even more particular embodiment, the substrate is glass, quartz, sapphire, polyethylene terephthalate (PET), polyethylene naphthalate (PEN), polyethersulphone (PES), polycarbonate (PC), polyimide (PI) or a combination thereof. In an even more particular embodiment, the titanium connected group has the general formula TiₘOₓC_{y}H_{z}, wherein m, x, y, z is independent integer. In one more particular embodiment, the index-matching coating includes a metal oxide coating, wherein application of the metal oxide coating creates a refractive index differential between 0 and 1 between the metal oxide coating and the transparent electrically conductive layer. In an even more particular embodiment, the metal oxide coating is formed by curing at a temperature of at least 50° C. to form the index-matching layer on the substrate. In one embodiment, the metal oxide coating is applied having a thickness between 5 nm to 100 nm and the coating has a refractive index between 1.5 and 2.0. In one more particular embodiment, the index-matching coating is applied as a single metal oxide coating on the substrate. In one more particular embodiment, applying the transparent electrically conductive layer to the substrate is done by sputtering, spin coating, spray coating, and slit coating. In one more particular embodiment, applying the metal oxide coating to the substrate is done by spin coating, spray coating, and slit coating. In one more particular embodiment, the metal oxide layers may be further selectively etched by fluorine contained chemicals.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 illustrates a sectional side view of an exemplary optical device without an index matching layer.

FIG. 2A illustrates a sectional side view of the exemplary optical device of FIG. 1 coated with an index matching layer with a single metal oxide layer.

FIG. 2B illustrates a sectional side view of the exemplary optical device of FIG. 1 coated with an alternate index matching layer with a single metal oxide layer.

FIG. 2C illustrates a sectional side view of the exemplary optical device of FIG. 1 coated with an alternate index matching layer combination of two independent metal oxide layers.

FIG. 3A illustrates a sectional side view of the exemplary optical device of FIG. 1 coated with an alternate index matching layer combination of one metal oxide layer and one silicon oxide layer.

FIG. 3B illustrates a sectional side view of the exemplary optical device of FIG. 1 coated with an alternate index matching layer combination of one metal oxide layer and one silicon oxide layer.

FIG. 3C illustrates a sectional side view of the exemplary optical device of FIG. 1 coated with an alternate index matching layer combination of one metal oxide layer and two silicon oxide layers.

FIG. 4 illustrates an exemplary method of forming the exemplary optical device of FIGS. 2A-2C with the index matching layers.

FIG. 5 illustrates another exemplary method of forming the exemplary optical device of FIGS. 3A-3C with the index matching layers.

Corresponding reference characters indicate corresponding parts throughout the several views. The exemplifications set out herein are provided to illustrate certain exemplary embodiments and such exemplifications are not to be construed as limiting the scope in any manner.

### DETAILED DESCRIPTION

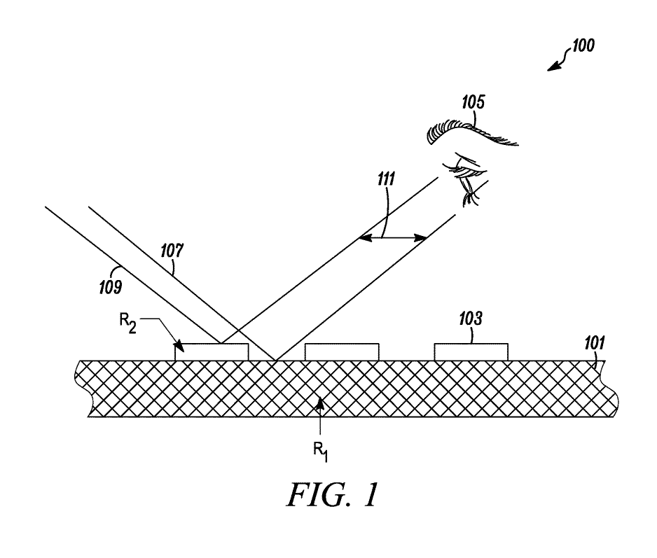

Referring first to FIG. 1, an exemplary optical device 100 is illustrated. Optical device 100 may be rigid or flexible. Optical device 100 may be flat or non-flat. Optical device 100 includes a substrate 101. Substrate 101 may be comprised of materials such as inorganic materials (e.g., glass, quartz, sapphire, etc.) or plastic films (e.g., polyethylene terephthalate (PET), polyethylene naphthalate (PEN), polycarbonate (PC), polyethersulphone (PES), polyimide (PI), etc.) or a combination thereof. In some exemplary embodiments, substrate 101 comprises a portion of optical device 100, such as a touch screen of a smartphone, mobile or laptop computer, or other computing device.

As illustrated in FIG. 1, substrate 101 includes a transparent conductive oxide (TCO) layer 103 positioned along an upper surface of substrate 101. In the illustrative embodiment, TCO layer 103 comprises grids of transparent, electrically conductive materials. In some embodiments, TCO layer 103 may be comprised of compounds such as indium tin oxide (ITO), antimony tin oxide (ATO), aluminum zinc oxide (AZO), etc. TCO layer 103 may also include materials such as Cr, Ag, or Ag nanowires/nano ink, semiconductor parts such as silicon, silicon compounds, carbon materials such as carbon nanotubes, graphene, organic transparent conductive layers such as poly(3,4-ethylenedioxythiophene) (PEDOT), or any combination of these.

As further shown in FIG. 1, a user's eye 105 is directed in a downward direction such that eye 105 perceives a reflection of light 107 from substrate 101 and a reflection of light 109 from TCO layer 103 to perceive optical device 100.

Reflections of light 107, 109 correspond with refractive indexes R₁, R₂, respectively. R₁ is the refractive index of substrate 101, while R₂ is the refractive index of TCO layer 103. In the illustrative embodiment, R₂ is not equal to R₁ resulting in a refractive index differential 111. When refractive index differential 111 is substantially large, a user can perceive the configuration of TCO layer 103 as positioned along substrate 101. In some exemplary embodiments, refractive index R₁ may be as little as 1.3, 1.35, 1.4, 1.45, 1.5, 1.55, as great as 1.6, 1.65, 1.7, 1.75, 1.8 or within any range defined between any two of the foregoing values, such as 1.4 to 1.7. In some exemplary embodiments, R₂ may be as little as 2.0, 2.05, 2.1, 2.15, 2.2, as great as 2.25, 2.3, 2.35, 2.4, 2.45, 2.5 or within any ranged defined between any two of the foregoing values, such as 2.1 to 2.4.

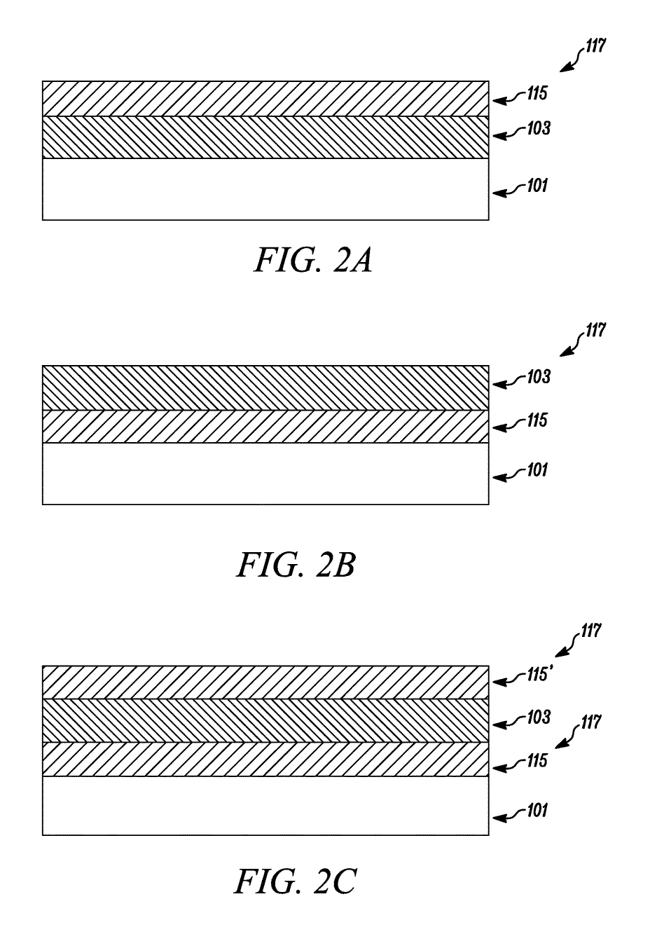

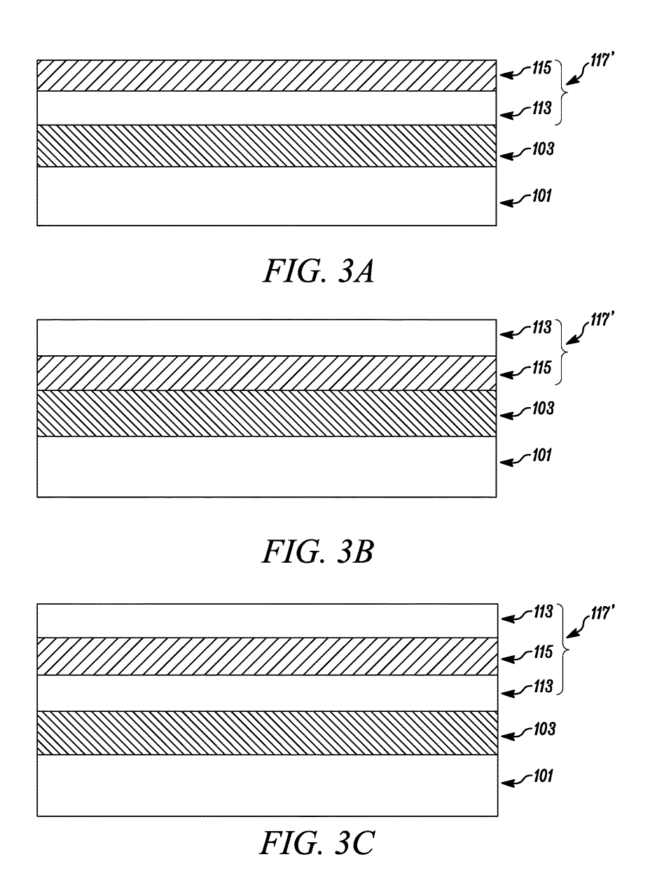

Exemplary configurations of substrates and index matching layers in accordance with the present disclosure are described below with reference to FIGS. 2A-2C and 3A-3C, followed by a description of exemplary application methods and the chemical composition of such layers.

Referring now to FIGS. 2A-2C, substrate 101 has two types of layers, a metal oxide layer 115 as an index matching layer 117 and a TCO layer 103, positioned on top of the upper surface of substrate 101. TCO layer 103 and metal oxide layer 115 can be arranged such that TCO layer 103 is underneath metal oxide layer 115 and between substrate 101 and metal oxide layer 115. In an alternate embodiment, TCO layer 103 is positioned such that index matching layer 115 is underneath TCO layer 103 and between substrate 101 and TCO layer 103 (FIG. 2B). In another alternate embodiment, a sandwich structure of layers 103 and index matching layer 117 may be present along the upper surface of substrate 101 such that TCO layer 103 is positioned beneath metal oxide layer 115′ and above metal oxide layer 115. This plurality of layers is positioned along the upper surface of substrate 101 (FIG. 2C).

Other configurations of optical device 100 that reduce refractive index differential 111 are shown in FIGS. 3A-3C. As shown in FIGS. 3A-3C, an index matching layer 117′ includes a combination of metal oxide layer 115 and siloxane layer 113. For example, in one embodiment, index matching layer 117 includes a single siloxane layer 113 and a single metal oxide layer 115 positioned on top on one another (FIGS. 3A & 3B). In an alternate embodiment, index matching layer 117 includes a plurality of siloxane layers 113, 113′ with a single metal oxide layer 115 (e.g., FIG. 3C). In a further alternate embodiment, index matching layer 117 includes a plurality of siloxane layers 113 with a plurality of metal oxide layers 115. In a further alternate embodiment, a metal oxide layer 115 and a siloxane layer 113 are applied alternately.

Metal oxide layer 115 may be a sol-gel type polymer formed by hydrolysis and condensation of silicon-containing monomers. The polymer is based on the condensation of Ti(OR)₄ monomers, with an added amounts of Si(OR)₄ monomers for tuning the polymer's refractive index. Metal oxide layer 115 includes both titanium oxide and silicon oxide and has a refractive index that may be as little as 1.4, 1.45, 1.5, 1.55, 1.6, 1.65, 1.7, 1.75, as great as 1.8, 1.85, 1.9, 1.95, 2.0, 2.05, 2.1 or within any range defined between any two of the foregoing values, such as 1.5 to 2.0. In one exemplary embodiment, the polymer of index matching layer 115 has a high TiO/SiO ratio, allowing a high refractive index to be selectively achieved within a refractive index range of 1.5 to 2.0.

Each layer of index matching layer 117, 117′ is applied onto substrate 101 by spin or slot die coating followed by curing. In an exemplary embodiment, each layer of index matching layer 117, 117′ is applied onto substrate 101 as a single coating with a thickness that may be as little as 1 nm, 5 nm, 10 nm, 15 nm, 20 nm, 25 nm, 30 nm, 35 nm, 40 nm, 45 nm, 50 nm, as great as 80 nm, 85 nm, 90 nm, 95 nm, 100 nm, 105 nm, 110 nm or within any range defined between any two of the foregoing values, such as 5 nm to 100 nm.

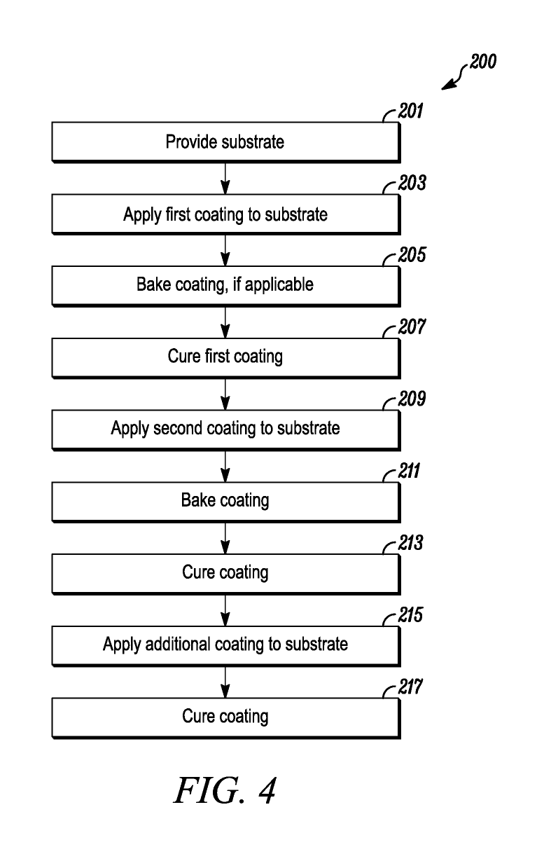

Referring next to FIG. 4, an exemplary method 200 of forming a coated electronic device 100 is illustrated. At block 201, a substrate 101, such as glass or plastic film (FIG. 1) is provided.

At block 203, a first layer of material is applied to a first side of substrate 101. In some embodiments, the first layer of material includes TCO layer 103. In alternate embodiments, the first layer of material includes metal oxide layer 115, which is a liquid formulation. Exemplary methods for applying the liquid formulation of metal oxide layer 115 include spin coating, spray coating, dip coating, slit coating, roller coating, Meyer rod coating, casting, and the like. In one exemplary embodiment, the liquid coating formulation is selectively etched by fluorine contained chemicals. In one exemplary embodiment, the liquid coating formulation is applied by spin coating at a speed as low as about 2000 rpm, about 3000 rpm, about 3300 rpm, as high as about 3500 rpm, 4000 rpm, about 5000 rpm, or within any range defined between any two of the foregoing values, such as 2000 rpm to 5000 rpm, 3000 rpm to 4000 rpm, or 3300 rpm to 3500 rpm.

At block 205, the coated substrate of block 203 is optionally baked to remove at least a portion or all of the solvent from the liquid formulation of index matching layer 117 if applied to substrate 101. In some embodiments, the baking step is as short as 1 minute, 5 minutes, 10 minutes, 15 minutes, as long as 20 minutes, 30 minutes, 45 minutes, 60 minutes, or longer, or within any range defined between any two of the foregoing values, such as 1 minute to 60 minutes, 5 minutes to 30 minutes, or 10 minutes to 15 minutes. In some embodiments the baking step is conducted at a temperature as low as 100° C., 200° C., 220° C., as high as 250° C., 275° C., 300° C., 320° C., 350° C., or higher, or within any range defined between any two of the foregoing values, such as 100° C. to 350° C., 200° C. to 300° C., or 220° C. to 275° C. In some embodiments, the baking is performed by heating the coated substrate for about 10 minutes at about 200° C. In an alternate embodiment, the baking steps may also include multiple steps of heating at different baking temperatures within the values mentioned above.

At block 207, the first coating is cured. Exemplary curing methods include thermal treatment, light curing, UV curing, and microwave curing.

In some embodiments, the curing step is performed by heating the coated substrate for as short as 1 minute, 5 minutes, 10 minutes, 20 minutes, as long as 30 minutes, 45 minutes, 60 minutes, 120 minutes or longer, or within any range defined between any two of the foregoing values. In alternate embodiments, the baking step is conducted at a temperature as low as 100° C., 200° C., 220° C., as high as 250° C., 275° C., 300° C., 320° C., 350° C., 400° C., 500° C., or higher, or within any range defined between any two of the foregoing values, such as 100° C. to 350° C., 200° C. to 300° C., or 220° C. to 275° C. In some embodiments, the cure steps may also include multiple stages of heating at different curing temperatures mentioned above.

In one exemplary embodiment, the curing is performed by heating the coated substrate for as short as 3 minutes, 5 minutes, as long as 25 minutes, 60 minutes, or 90 minutes, or within any range defined between any two of the foregoing values, such as 3 minute to 60 minutes or 5 minutes to 25 minutes. In some embodiments the curing is performed by heating the coated substrate to a temperature as low as 100° C., 200° C., 220° C., as high as 250° C., 275° C., 300° C., 320° C., 350° C., 400° C., 500° C., or higher, or within any range defined between any two of the foregoing values, such as 100° C. to 350° C., 200° C. to 300° C., or 220° C. to 275° C. In some embodiments, the curing is performed by heating the coated substrate for about 60 minutes at about 250° C.

In some exemplary embodiments, heating is performed using an oven, furnace, or hot plate. In an alternate embodiment, heating can be done in an ambient atmosphere in the absence of additional gases. In an alternate embodiment, heating can be done in a gaseous environment with active gases, such as oxygen, NH₃, H₂O, CO₂. In an alternate embodiment, heating can be done in a gaseous environment with inert gases, such as nitrogen, helium, neon, argon, krypton, xenon, and radon. In an alternate embodiment, heating can be done in a gaseous environment with a blend of any types of gases mentioned above.

As shown in FIGS. 2A-2C, a second coating is applied to the substrate, as shown in block 209. In some exemplary embodiments, the second coating includes applying TCO layer 103 onto the first coating of metal oxide layer 115 previously applied in block 203. In other exemplary embodiments, the second coating includes applying metal oxide layer 115 onto TCO layer 103 previously applied in block 203. Exemplary methods for applying index matching layer 117 as the second liquid coating formulation include spin coating, spray coating, dip coating, slit coating, roller coating, Meyer rod coating, casting, and the like. In one exemplary embodiment, the liquid coating formulation is selectively etched by fluorine contained chemicals. In one exemplary embodiment, the second liquid coating formulation is applied by spin coating at a speed as low as about 2000 rpm, about 3000 rpm, about 3300 rpm, as high as about 3500 rpm, 4000 rpm, about 5000 rpm, or within any range defined between any two of the foregoing values, such as 2000 rpm to 5000 rpm, 3000 rpm to 4000 rpm, or 3300 rpm to 3500 rpm.

In block 211, the coated substrate is baked to remove at least a portion or all of the solvent from the second liquid coating formulation. In some embodiments, the baking step is performed as described above with respect to block 205.

In block 213, the second coating is cured. In some embodiments, the curing step is performed as described above with respect to block 207.

In some exemplary embodiments, an additional metal oxide layer 115′ (see FIG. 2C) is applied to electronic device 100, as shown in block 215. As shown in FIG. 2C, metal oxide layer 115′ is applied onto the underlying, previously applied layers, namely, TCO layer 103 and index matching layer 115.

In block 217, the additional metal oxide layer 115′, if present, may be cured (see FIG. 2C). In some embodiments, curing metal oxide layer 115′ is performed by heating the coated substrate for as short as 1 minute, 5 minutes, 10 minutes, 20 minutes, as long as 30 minutes, 45 minutes, 60 minutes, 120 minutes or longer, or within any range defined between any two of the foregoing values. In some embodiments the baking step is conducted at a temperature as low as 100° C., 200° C., 220° C., as high as 250° C., 275° C., 300° C., 320° C., 350° C., 400° C., 500° C., or higher, or within any range defined between any two of the foregoing values, such as 100° C. to 350° C., 200° C. to 300° C., or 220° C. to 275° C. In some embodiments, cure steps may also comprise multiple stages of heating at different curing temperatures mentioned above.

In other exemplary embodiments, the additional layer may be applied through a process, such as physical vapor deposition (PVD) or chemical vapor deposition (CVD), which does not require curing.

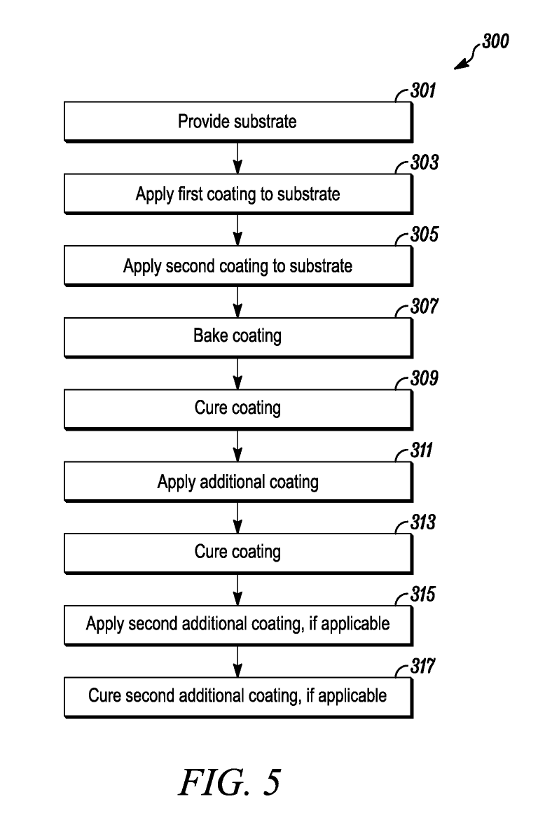

Referring next to FIG. 5, another exemplary method 300 of forming an index matched electronic device 100 is illustrated. In some embodiments, method 300 is similar to method 200, and similar numbers are used to indicate similar blocks. At block 301, a substrate 101, such as glass or plastic film (FIG. 1) is provided. At block 303, a first coating is applied to a first side of substrate 101. In some exemplary embodiments, applying the first coating includes applying TCO layer 103 onto substrate 101. At block 305, a second coating is applied to substrate 101. In some exemplary embodiments, the second coating comprises metal oxide layer 115. In other exemplary embodiments, the second coating comprises siloxane layer 113. Method 300 then proceeds to blocks 307 and 309 where the second coating is baked to remove at least a portion or all of the solvent from the second coating (block 307) and cured (block 309). In some embodiments, the baking step is performed as described above with respect to block 205. In some embodiments, the curing step in block 309 is performed as described above with respect to block 207 of method 200.

In block 311, an additional coating is applied to substrate 101. In some exemplary embodiments, the additional coating is metal oxide layer 115 applied to the previously applied siloxane layer 113. In other embodiments, the additional coating is siloxane layer applied to the previously applied metal oxide layer 115. In block 313, the additional coating is cured. In some embodiments, the curing step in block 313 is performed as described above with respect to block 207 of method 200. In some exemplary embodiments, a second additional coating (see FIG. 3C) is applied to substrate 101, as shown in block 315. In some exemplary embodiments, the second additional coating includes siloxane layer 113. In block 317, the second additional coating, if present, may be cured. In other exemplary embodiments, the additional layer may be applied through a process, such as physical vapor deposition (PVD) or chemical vapor deposition (CVD), which does not require curing.

I. Index Matching Layer Formulation

Index matching layers 117,117′ may comprise at least one high refractive index layer and optionally, further low refractive index layer. The high refractive index layer may include a metal oxide layer 115, 115′ with refractive index of at least 1.5. The low refractive index layer may include a silicon oxide layer 113 with refractive index of at most 1.6. As shown in FIGS. 2A-2C and 3A-3C, index matching layer 117, 117′ comprises metal oxide layer 115, 115′ and optionally silicon oxide layer 113.

In an exemplary embodiment, metal oxide layer 115,115′ may be formed by wet deposition. The wet formulation or liquid formulation forming metal oxide layer 115, 115′ includes a precursor polymer, solvents and optional additives if required. In an exemplary embodiment, silicon oxide layer 113 may be formed from wet deposition or dry deposition. The wet formulation or liquid formulation forming silicon oxide layer 113 includes siloxane, solvents and optional additives if required. Exemplary methods for the wet deposition include spin coating, spray coating, dip coating, slit coating, roller coating, Meyer rod coating, casting, and the like. Exemplary methods for the dry deposition include CVD (chemical vapor deposition) and PECVD (plasma enhanced chemical vapor depotion), and the like.

a. Metal Oxide Precursor Polymer

Index matching layer 117, 117′ comprises metal oxide layer 115. In one exemplary embodiment, the formulation for forming metal oxide layer 115 involves the hydrolysis and condensation of silicon-containing and titanium monomers as described below.

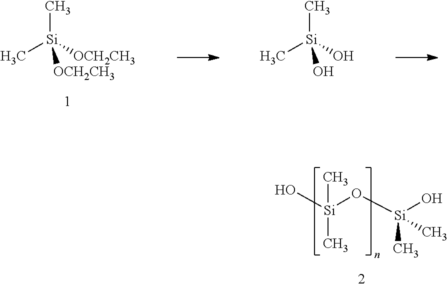

The exemplary reaction shown above involves the hydrolysis of silicon based material 1 as discussed further below. The silicon based material 1 may be placed in an acidic solution with deionized water to yield hydrolyzed silicon based compound 2. Exemplary acidic solutions include nitric acid, acetic acid, hydrochloric acide, sulfuric acid, or phosphoric acid with deionized water. In alternate emdodiments, the acidic solutions include acetic anhydride, sulfuric anhydride, pyrophosphoric acid, polyphosphoric acid with deionized water.

Exemplary reaction temperatures may be as little as little as 0° C., 5° C., 10° C., as high as 20° C., 25° C., 30° C., 50° C., 80° C., 150° C., or within any range defined between any two of the foregoing values, such as 0° C. to 10° C. In an exemplary reaction, the reaction is conducted at room temperature.

Exemplary reaction times may be as little as 20 minutes, 60 minutes, 240 minutes, 480 minutes, as great as 640 minutes, 720 minutes, 4800 minutes, 14400 minutes, or within any range defined between any two of the foregoing values, such as 20 minutes to 720 minutes. In an exemplary reaction, the reaction time is 30 minutes.

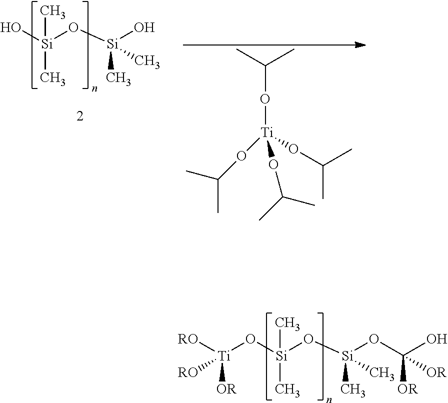

After hydrolysis, hydrolyzed silicon-based compound 2 undergoes a second reaction shown above. The exemplary reaction shown above involves the condensation and polymerization of hydrolyzed silicon-based compound 2.

In the exemplary reaction, a metal oxide monomer is added to hydrolyzed silicon-based compound 2 at an exemplary temperature. Once the metal oxide is added, the solution is heated for a predetermined period of time after which the polymer of the index matching layer as shown below in Formula (I) is formed. The metal oxide monomer has a general structure of (R—O—)ₙM, (R—COO—)ₙM, or (R—CO—CH═C(R′)—O)ₙM, R is an alkyl group with the number of carbons ranging from 1-8, R′ is an alkyl group with the number of carbons ranging from 1-5, n is integer 2-4, M is a metal element, Ti, Zr, Al, Hf, Sn, W. In one embodiment, the metal oxide monomer is Titanium (IV) isopropoxide. In an alternate embodiment, the metal oxide monomer may be Titanium(IV) n-butoxide, Titanium(IV) tetraacetate or Tetrakis(2,4-pentanedionato)zirconium(IV).

Exemplary reaction temperatures may be as little as 0° C., 5° C., 10° C., as high as 20° C., 25° C., 30° C., 50° C., 80° C., 150° C., or within any range defined between any two of the foregoing values, such as 0° C. to 30° C. In an exemplary reaction, the reaction is conducted at room temperature.

Exemplary heating temperatures may be as little as 50° C., 55° C., 60° C., as high as 65° C., 70° C., 75° C., or within any range defined between any two of the foregoing values, such as 55° C. to 65° C. In an exemplary reaction, the reaction is heated at 60° C.

Exemplary heating times may be as little as 20 minutes, 1 hour, 3 hours, 6 hours, 6.5 hours, 7 hours, 7.5 hours, 8 hours, as great as 9 hours, 9.5 hours, 10 hours, 25 hours, 50 hours, 100 hours, 240 hours, or within any range defined between any two of the foregoing values, such as 6 hours to 10 hours. In an exemplary reaction, the heating time is 8 hours.

The resulting metal oxide layer comprises a sol-gel polymer including a metal oxide precursor polymer. The composition includes a precursor polymer of Formula (I), shown below, where each R1 is an independent hydrogen, an alkyl group having 1 to 6 carbons, alkylene oxide, or titanium connected groups, where the titanium connected groups have the general formula TiₘOₓC_{y}H_{z}, wherein the m, x, y, and z are independent integers. For example, the titanium connected groups include Ti(OC₃H₆)₃ and Ti(OC₄H₉)₃. In an exemplary embodiment, the titanium connected groups include any organic or inorganic groups connected to the titanium atom. In a further exemplary embodiment, R1 includes C₃H₆ and C₄H₉. Each R2 is an independent hydrogen or an alkyl group.

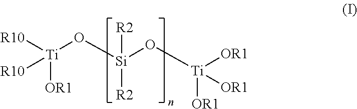

Exemplary silicon-based materials include MOX available from Honeywell International, Inc. In one exemplary embodiment, MOX-HFA-15 is applied. MOX-HFA-15, available from Honeywell International Inc., is polymer solution with the precursor polymer having the general formula of Formula (I) above, where R2 is CH₃, n is below 5, R1 may include H, C₃H₆, C₄H₉ and further titanium connected groups, and where the metal oxide monomer is titanium(IV) isopropoxide

Other exemplary metal oxide precursor polymers are disclosed in U.S. Patent No. WO 2014/197346, entitled LIQUID TITANIUM OXIDE COMPOSITIONS, METHODS FOR FORMING THE SAME, AND METHODS FOR ETCHING MATERIAL LAYERS OF OR OVERLYING SUBSTRATES USING THE SAME, the disclosure of which is hereby incorporated by reference in its entirety.

b. Silicon-Based Materials

Index matching layer 117, 117′ optionally includes a silicon oxide layer 113. The formulation for forming silicon oxide layer 113 includes one or more crosslinkable silicon-based materials that can be crosslinked.

Exemplary silicon-based materials comprise one or more crosslinkable siloxane oligomers formed from one or more organoalkoxysilane precursors via hydrolysis and condensation reactions. Exemplary organoalkoxysilane precursors include tetraethylorthosilicate (TEOS), methyltrimethoxysilane (MTMOS), methyltriethoxysilane (MTEOS), dimethyldiethoxysilane (DMDEOS), phenyl triethoxysilane (PTEOS), vinyltriethoxysilane (VTEOS), dimethyldimethoxysilane, phenyltrimethoxysilane, and combinations of the foregoing.

In some exemplary embodiments, the one or more crosslinkable siloxane oligomers comprise a methylsiloxane oligomer. In some embodiments, methyl groups comprise as little as 0 wt. %, 1 wt. %, 2 wt. %, 5 wt. %, as great as 10 wt. %, 15 wt. %, 20 wt. % of the crosslinkable siloxane oligomers, or may be within any range defined between any two of the foregoing values, such as from 1 wt. % to 20 wt. %, 2 wt. % to 15 wt. %, or 5 wt. % to 15 wt. %. In some embodiments, the methyl groups comprise about 10 wt. % of the total crosslinkable siloxane oligomers.

In some embodiments, the crosslinkable siloxane oligomers have a weight average molecular weight as little as 500 Dalton, 1000 Dalton, 1250 Dalton, 1500 Dalton, as high as 1600 Dalton, 1750 Dalton, 2000 Dalton, 3000 Dalton, 5000 Dalton, or within any range defined between any two of the foregoing values, such as 500 Dalton to 5000 Dalton, or 1000 Dalton to 3000 Dalton, or 1500 Dalton to 2000 Dalton. In some embodiments, the crosslinkable siloxane oligomers have a polydispersity index (weight average molecular weight/number average molecular weight) as little as 1.10, 1.12, 1.15, as high as 1.16, 1.18, 1.20, or within any range defined between any two of the foregoing values, such as 1.10 to 1.20, 1.12 to 1.18, or 1.15 to 1.18. In some embodiments, the crosslinkable siloxane oligomers have a weight average molecular weight of about 1500 and a polydispersity index of about 1.16.

In some embodiments, the crosslinkable siloxane oligomers are provided as a plurality of particles having a particle diameter as little as 1 nm, 2 nm, 3 nm, 5 nm, as great as 10 nm, 30 nm, 40 nm, 50 nm, or within any range defined between any two of the foregoing values, such as from 1 nm to 50 nm, 2 nm to 40 nm, or 3 nm to 30 nm. In some embodiments, the particles have a relatively uniform particle diameter. In another exemplary embodiment, DMDEOS is used as a precursor for forming the index matching layer.

In one exemplary embodiment, formulation comprises the one or more silicon-based materials in an amount as little as 1.0 wt. %, 1.5 wt. %, 2.0 wt. %, as great as 10 wt. %, 15 wt. %, 20 wt. %, based on the total weight of the formulation, or within any range defined between any two of the foregoing values, such as 1.0 wt. % to 20 wt. %, 1.5 wt. % to 15 wt. %, or 2.0 wt. % to 10 wt. %.

c. Solvent

The wet formulation for metal oxide layer 115, 115′, and the wet formulation for silicon oxide layer 113 each independently include one or more solvents. In some contemplated embodiments, the solvent or solvent mixture (comprising at least two solvents) comprises those solvents that are considered part of the hydrocarbon family of solvents. Contemplated hydrocarbon solvents include toluene, xylene, p-xylene, mxylene, mesitylene, solvent naphtha H, solvent naphtha A, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosine, isobutylbenzene, methylnaphthalene, ethyltoluene, ligroine.

In other contemplated embodiments, the solvent or solvent mixture may comprise those solvents that are not considered part of the hydrocarbon solvent family of compounds, such as ketones, such as acetone, diethyl ketone, methyl ethyl ketone and the like, alcohols, esters, ethers, amides and amines. In yet other contemplated embodiments, the solvent or solvent mixture may comprise a combination of any of the solvents mentioned herein. Contemplated solvents may also comprise aprotic solvents, for example, cyclic ketones such as cyclopentanone, cyclohexanone, cycloheptanone, and cyclooctanone; cyclic amides such as N-alkylpyrrolidinone, wherein the alkyl has from about 1 to 4 carbon atoms; N-cyclohexylpyrrolidinone and mixtures thereof.

Other organic solvents may be used herein insofar as they are able to aid dissolution of an adhesion promoter (if used) and at the same time effectively control the viscosity of the resulting solution as a coating solution. It is contemplated that various methods such as stirring and/or heating may be used to aid in the dissolution. Other suitable solvents include methyethylketone, methylisobutylketone, dibutyl ether, cyclic dimethylpolysiloxanes, butyrolactone, y-butyrolactone, 2-heptanone, ethyl 3-ethoxypropionate, 1-methyl-2-pyrrolidinone, propylene glycol methyl ether acetate (PGMEA), hydrocarbon solvents, such as mesitylene, xylenes, benzene, toluene di-n-butyl ether, anisole, acetone, 3-pentanone, 2-heptanone, ethyl acetate, n-propyl acetate, n-butyl acetate, ethyl lactate, ethanol, 2-propanol, dimethyl acetamide, propylene glycol methyl ether acetate, and/or combinations thereof. It is contemplated and preferred that the solvent does not react with the silicon-containing monomer or pre-polymer component.

Other exemplary solvents include water, nitric acid, alcohols such as methanol, ethanol, isopropyl alcohol, n-propanol, n-butanol, and mixtures thereof. In one exemplary embodiment, the solvent comprises a mixture of nitric acid, water, and 1-methoxy-2-propanol.

In one exemplary embodiment, the present formulation comprises a total amount of solvent as little as 80 wt. %, 81 wt. %, 82 wt. %, 85 wt. %, 88 wt. %, as great as 90 wt. %, 92 wt. %, 95 wt. %, 97 wt. %, 98 wt. %, 99 wt. %, based on the total weight of the formulation, or within any range defined between any two of the foregoing values, such as 80 wt. % to 99 wt. %, 81 wt. % to 98 wt. %, 82 wt. % to 97 wt. %, 85 wt. % to 97 wt. %, or 88 wt. % to 97 wt. %.

d. Other Additives

Optionally, the wet formulation for metal oxide layer 115, 115′, and the wet formulation for silicon oxide layer 113 each may independently further include one or more additives. In some exemplary embodiments, the formulation includes one or more catalysts to improve the crosslinking of the silicon-based material. Exemplary catalysts include organic substituted ammonium hydroxide, such as TMAH (tetramethylammonium hydroxide), or organic substituted ammonium salts, such as TMAN (tetramethylammonium nitride). In some embodiments, the formulation comprises a total amount of catalyst as little as 0 wt. %, 0.001 wt. %, 0.01 wt. %, as great as 0.1 wt. %, 0.2 wt. %, 1.0 wt. %, based on the total weight of the formulation, or within any range defined between any two of the foregoing values, such as 0 wt. % to 1.0 wt. %, 0.01 wt. % to 0.1 wt. %, or 0.001 wt. % to 0.1 wt. %.

In some exemplary embodiments, the formulation includes one or more surfactants to improve the leveling of the silicon-based materials on sapphire substrate. Exemplary surfactants include silicone based surface additives such as: BYK-307, BYK-306, BYK-222 provided by BYK Chemie GmbH, fluorosurfactants, such as Novec™ Fluorosurfactant FC-4430 provided by 3M, or Tego® Flow 300 provided by Evonik Industries AG. In some embodiments, the formulation comprises a total amount of surfactant as little as 0 wt. %, 0.001 wt. %, 0.01 wt. %, as great as 0.1 wt. %, 0.2 wt. %, 1.0 wt. %, based on the total weight of the formulation, or within any range defined between any two of the foregoing values, such as 0 wt. % to 1.0 wt. %, 0.01 wt. % to 0.1 wt. %, or 0.001 wt. % to 0.1 wt. %.

II. Coating

In some exemplary embodiments, the metal oxide precursor polymer formulation forms a coating on a substrate, such as a glass or plastic film.

In some exemplary embodiments, the coating may be applied on the substrate by a wet deposition and curing process. Exemplary methods for the wet deposition include spin coating, spray coating, dip coating, slit coating, roller coating, Meyer rod coating, casting, and the like. Exemplary methods for curing include thermal curing or call heat treatment.

In some exemplary embodiments, the coating has a thickness as little as 1 nm, 5 nm, 10 nm, 15 nm, 20 nm, 25 nm, 30 nm, 35 nm, 40 nm, 45 nm, 50 nm, as great as 80 nm, 85 nm, 90 nm, 95 nm, 100 nm, 105 nm, 110 nm or within any range defined between any two of the foregoing values, such as 10 nm to 80 nm.

In some exemplary embodiments, a substrate 101 is coated with the index matching formulation has a transmittance to light in the visible optical wavelength range from 380 to 800 nm.

The transmittance test method follows the testing methodology of ASTM D1003. The average transmittance of the 380-800 nm spectrum was measured using a Cary4000 spectrophotometer, the average transmittance of the 400 nm-700 nm spectrum and haze for a bare sapphire were measured using a BYK Haze Gard. Typically, a 100% transmittance calibration scan over the spectral range of interest with no sample is conducted followed by a 0% transmittance scan with an opaque sample in the sample beam that does not interfere with the reference beam in the same sample compartment. The transmittance spectrum of the sample of interest is then scanned and measured. In some embodiments, the optical transmittance is as high as 85%, 86%, 88%, 89%, 90%, 92%, 95%, 97%, 98%, 99%, or higher, or within any range defined between any two of the foregoing values, such as 87% to 90%, or 88% to 92%.

In some exemplary embodiments, the metal oxide precursor polymer formulation forms a coating having a refractive index that is as little as 1.4, 1.45, 1.5, 1.55, 1.6, 1.65, 1.7, 1.75, as great as 1.8, 1.85, 1.9, 1.95, 2.0, 2.05, 2.1 or within any range defined between any two of the foregoing values, such as 1.5 to 2.0. In one exemplary embodiment, the polymer of index matching layer 115 has a high TiO/SiO ratio, allowing a high refractive index to be selectively achieved within a refractive index range of 1.5 to 2.0.

### EXAMPLES

### Example 1

A substrate having standard display glass and an ITO pattern deposited onto the standard display glass is used. The ITO glass has a surface conductivity of 100 ohm/square. Further, MOX-HFA-15, one of liquid titanium polymer, provided by Honeywell International, is casted on the silicone oxide surface by a spin coater with different spin speeds and spin times. After baking the electronic device for 60 minutes at 250° C., the transmittance of the ITO area is tested by a spectrometer and the index matching performance is examined with the human eye.

### Example 2

A substrate having standard display glass and an ITO pattern deposited onto the standard display glass is used. The ITO glass has a surface conductivity of 100 ohm/square. Silicone oxide is deposited by Plasma Enhanced Chemical Vapor Deposition (PECVD) on the ITO pattern with a thickness of 38 nm. Further, MOX-HFA-15 is casted on the silicone oxide surface by a spin coater with different spin speeds and spin times. After baking the electronic device for 60 minutes at 250° C., the transmittance of the ITO area is tested by a spectrometer and the index matching performance is examined by the human eye as discussed in Example 1.

### Example 3

A substrate having standard display glass and an ITO pattern deposited onto the standard display glass is used. The ITO glass has a surface conductivity of 30 ohm/sq. Further, MOX-HFA-15 is casted on the silicone oxide surface by a spin coater with different spin speeds and spin times. After baking the electronic device for 60 minutes at 250° C., the transmittance of the ITO area is tested by a spectrometer and the index matching performance is examined by the human eye as discussed in Example 1.

### Example 4

A substrate having standard display glass and an ITO pattern deposited onto the standard display glass is used. The ITO glass has a surface conductivity of 30 ohm/sq. Silicone oxide is deposited by PECVD on the ITO pattern with a thickness of 38 nm. Further, MOX-HFA-15 is casted on the silicone oxide surface by a spin coater with different spin speeds and spin times. After baking the electronic device for 60 minutes at 250° C., the transmittance of the ITO area is tested by a spectrometer and the index matching performance is examined by the human eye as discussed in Example 1.

Table 1 below shows the above discussed examples and their respective transmittance and index matching characteristics. For measuring the index matching effect of the applied layer, the substrate is examined by the naked eye to see if the “ITO shadow” has been lessened. An “X” designation means the index matching effect is poor, a “Δ” designation means there is some index matching effect but not enough, and an “O” designation means the index matching is very good.

As shown in Table 1 below, for substrates that have a high ITO resistance, an index matching layer that includes a siloxane layer showed improved to good index matching with the TCO layer, i.e., the presence of the “ITO shadow” is lessened if not removed. Additionally, a similar result is reached for substrates with a low ITO resistance when an index matching layer that comprises both a metal oxide layer and a siloxane layer present and a high ITO resistance as well.

TABLE 1
Formulation of Examples 1 and 2

| | | | Index | Metal Oxide | | | | |
|---|---|---|---|---|---|---|---|---|
| | ITO | SiO₂ | Matching | Layer | | | | |
| | resistance | thickness | Coating | Thickness | Baking | Appearance | Transmittance | Index |
| Ex. | (ohm/sq) | (nm) | Process | (mm) | Conditions | after baking | (%) | matching |
| 1 | 100 | 0 | 1400 rpm | N/A | 250° C. | colorless | 86.1-87 | X |
| | | | 30 s | | 60 min | | | |
| | 100 | 0 | 1300 rpm | N/A | 250° C. | colorless | 85.8-86.4 | X |
| | | | 15 s | | 60 min | | | |
| 2 | 100 | 38 | 1400 rpm | N/A | 250° C. | colorless | 88.6-88.7 | Δ |
| | | | 30 s | | 60 min | | | |
| | 100 | 38 | 1300 rpm | N/A | 250° C. | light yellow | 88.9-89.5 | ◯ |
| | | | 15 s | | 60 min | | | |
| | 100 | 38 | 1000 rpm | N/A | 250° C. | light yellow | 89.4 | ◯ |
| | | | 15 s | | 60 min | | | |
| 3 | 30 | 0 | 1400 rpm | N/A | 250° C. | light blue | 80.4-81 | X |
| | | | 30 s | | 60 min | | | |
| | 30 | 0 | 1300 rpm | N/A | 250° C. | colorless | 80-80.7 | X |
| | | | 15 s | | 60 min | | | |
| | 30 | 0 | 1000 rpm | N/A | 250° C. | colorless | 80.3-80.7 | X |
| | | | 15 s | | 60 min | | | |
| 4 | 30 | 38 | 1400 rpm | N/A | 250° C. | light purple | 89.4-90.3 | Δ |
| | | | 30 s | | 60 min | with yellow | | |
| | 30 | 38 | 1300 rpm | N/A | 250° C. | light yellow | 90.3-90.7 | Δ |
| | | | 15 s | | 60 min | | | |
| | 30 | 38 | 1000 rpm | N/A | 250° C. | light purple | 90.9-91.1 | Δ |
| | | | 15 s | | 60 min | | | |
| | 30 | 38 | 900 rpm | 15.9 | 250° C. | light orange | 89.4-90 | ◯ |
| | | | 8 s | | 60 min | | | |
| | 30 | 38 | 600 rpm | 26.7 | 250° C. | purple red | 91.1-91.4 | X |
| | | | 8 s | | 60 min | | | |

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

1. A layered construct comprising:
a substrate;
a transparent electrically conductive layer positioned along an upper surface of the substrate; and
an index-matching layer positioned adjacent the transparent electrically conductive layer, said index-matching layer comprising:
a metal oxide layer containing titanium and having a refractive index of at least 1.5, the metal oxide layer having the structure below: 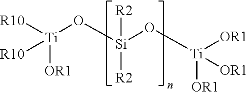
wherein each R1 is an independent hydrogen, an alkyl group having 1 to 6 carbons, alkylene oxide, or titanium connected groups
wherein each R2 is an independent hydrogen or an alkyl group.

2. The layered construct of claim 1, wherein the index-matching layer further comprises a silicon oxide layer.

3. The layered construct of claim 1, wherein the substrate is glass, quartz, sapphire, polyethylene terephthalate (PET), polyethylene naphthalate (PEN), polyethersulphone (PES), polycarbonate (PC), polyimide (PI) or a combination thereof.

4. The layered construct of claim 1, further comprising a refractive index differential between the transparent electrically conductive layer and the index-matching layer between 0 and 1.

5. The layered construct of claim 1, wherein the titanium connected groups has the general formula TiₘOₓC_{y}H_{z}, wherein m, x, y, z is independent integer.

6. The layered construct of claim 5, wherein the titanium connected groups include Ti(OC₃H₆)₃ and Ti(OC₄H₉)₃.

7. The layered construct of claim 1, wherein the R1 comprise C₃H₆ and C₄H₉.

8. The layered construct of claim 1, wherein the metal oxide layer has a refractive index from 1.5 to 2.0.

9. The layered construct of claim 1, wherein the metal oxide layer has a thickness between 5 to 100 nm.

10. The layered construct of claim 1, wherein the index-matching layer is applied as a single layer.

11. A method of forming a layered construct comprising:
providing a substrate;
applying a transparent electrically conductive layer to the substrate; and
applying an index-matching coating to the substrate;
wherein the index-matching coating is positioned adjacent the transparent electrically conductive layer, the index-matching coating comprising a metal oxide coating formed with the structure below: 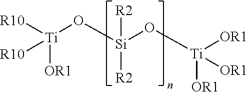
wherein each R1 is an independent hydrogen, an alkyl group having 1 to 6 carbons, alkylene oxide, or a titanium connected group, wherein the titanium connected group includes any organic or inorganic groups connected to the titanium atom;
wherein each R2 is an independent hydrogen or an alkyl group.

12. The method of claim 11, wherein the index-matching coating further includes a silicon oxide coating.

13. The method of claim 12, wherein the metal oxide coating and silicon oxide coating are applied alternately.

14. The method of claim 12, wherein applying the silicon oxide coating to the substrate is done by CVD, PECVD, spin coating, spray coating, and slit coating.

15. The method of claim 11, wherein the substrate is glass, quartz, sapphire, polyethylene terephthalate (PET), polyethylene naphthalate (PEN), polyethersulphone (PES), polycarbonate (PC), polyimide (PI) or a combination thereof.

16. The method of claim 11, wherein the titanium connected group has the general formula TiₘOₓC_{y}H_{z}, wherein m, x, y, z is independent integer.

17. The method of claim 11, wherein the index-matching coating includes a metal oxide coating, wherein application of the metal oxide coating creates a refractive index differential between 0 and 1 between the metal oxide coating and the transparent electrically conductive layer.

18. The method of claim 11, wherein the metal oxide coating is formed by curing at a temperature of at least 50° C. to form the index-matching layer on the substrate.

19. The method of claim 18, wherein the metal oxide coating is applied having a thickness between 5 nm to 100 nm and the coating has a refractive index between 1.5 and 2.0.

20. The method of claim 11, wherein the index-matching coating is applied as a single metal oxide coating on the substrate.

21. The method of claim 11, wherein applying the transparent electrically conductive layer to the substrate is done by sputtering, spin coating, spray coating, and slit coating.

22. The method of claim 11, wherein applying the metal oxide coating to the substrate is done by spin coating, spray coating, and slit coating.

23. The method of claim 11, wherein the index matching layers may be further selectively etched by fluorine contained chemicals.
